(19) United States
(12) Patent Application Publication
(10) Pub. No.: US 2006/0199399 A1
(43) Pub. Date: Sep. 7, 2006

(54) Surface manipulation and selective deposition processes using adsorbed halogen atoms

(76) Inventor: Anthony J. Muscat, Tucson, AZ (US)

Correspondence Address: PETERS VERNY JONES & SCHMITT, L.L.P., 425 SHERMAN AVENUE, SUITE 230, PALO ALTO, CA, 94306, US

(21) Appl. No.: 11/358,953

(22) Filed: Feb. 21, 2006

Related U.S. Application Data
(60) Provisional application No. 60/655,182, filed on Feb. 22, 2005.

(51) Int. Cl. H01L 21/26

(52) U.S. Cl. 438/798

(57) ABSTRACT

The present invention provides a surface preparation process using adsorbed halogen. The halogen is applied in a gas phase with UV light. The adsorbed halogen is subsequently modified in another gas phase reaction. The halogen may be reacted with water to form a hydroxyl-bearing Si—O monolayer that forms a layer for subsequent metal deposition. In one aspect the halogen layer is reacted with an alkyl or alkoxy of the formula R-OH to form a passivation layer. By replacing hydrogen atom termination with alkoxy (e.g.methoxy termination, —OCH₃). The selective deposition process can be used for passivating and depositing thin metal films on material surfaces composed of any combination of the group consisting of semiconductors, conductors, insulators, and the like.

### CROSS-REFERENCE TO RELATED APPLICATIONS

This application claims priority from Muscat, “SURFACE MANIPULATION AND SELECTIVE DEPOSITION PROCESSES USING ADSORBED HALOGEN,” U.S. Provisional Patent Application No. 60/655,182, filed on Feb. 22, 2005, which is hereby incorporated by reference in its entirety.

### STATEMENT OF GOVERNMENTAL SUPPORT

This invention was made with U.S. Government support under National Science Foundation Grant # EEC-9528813. The U.S. Government has certain rights in this invention.

### REFERENCE TO SEQUENCE LISTING OR COMPACT DISK

None

### BACKGROUND OF THE INVENTION

Selective deposition of materials on conductors, semiconductors, and insulators, is of great importance to many technology areas, and is particularly important in the manufacture of integrated circuits. In the past, selective deposition processes have tried to take advantage of sticking probability differences on surfaces with different chemical properties but were unsuccessful since the selectivity was not high enough. Moreover, past technologies have tried to enhance the selectivity of a metal on a conductor or semiconductor surface relative to an insulating surface, but have been unsuccessful in providing a manufacturable process. Papers listed below, and incorporated by reference herein, provide further information on problems with the state of the art in surface preparation and selective deposition processes.

1. Field of the Invention

The present invention relates to the field of improved processes for manipulating surface features, selective deposition, or both.

2. Related Art

The present invention relates to the field of improved processes for manipulating surface features, selective deposition, or both.

Since its inception in 1965, Moore's Law has acted as both a guide and a driving force for the semiconductor industry [1]. Device scaling has progressed to the point where the layers of material constructing a transistor have been reduced to only a few atoms [2]. While the creation of these ultra-thin films represents an engineering challenge in and of itself, surface preparation prior to deposition is also critical to the success of the deposited film.

The gate region of a transistor is the most sensitive structure in a device. Because the gate is the smallest portion of a device, the initial surface and the resulting layers are the most sensitive to contamination and variations in processing [3]. In order to continue the trend of Moore's Law and increase the speed of device operation, the gate stack has shrunk tremendously. The critical dimensions for this feature are currently centered on the 65 nm technology node, with a gate oxide thickness on the order of 20 Å, and even smaller devices under development [4, 5]. Given an oxide thickness of only a dozen or so atoms, even the lowest levels of contamination can result in a drastic change in device performance.

Due to this high sensitivity to contamination, cleanroom facilities and ultra-low particle chemicals were developed for the semiconductor industry. However, a high environmental and economic cost is associated with this manufacture. The shift from bulk quality chemicals to semiconductor grade results in approximately five times the byproducts per kilogram of product chemical [6]. Semiconductor construction also uses a tremendous amount of ultra-pure water. A standard fab can use over 1 million gallons of water a day, translating to an average of ten gallons of water per chip produced [7]. Both because of the tremendous use, and the expense of producing ultra-pure water, decreasing water use has become an important goal for the industry. Consumption of electricity for a cleanroom facility is also a large environmental and economic concern. On a square foot basis, a cleanroom facility uses 38-58 times more electricity than an office building and 7-15 times more electricity than an assembly line factory [8]. While the tools used in semiconductor device fabrication account for a sizeable portion of the electrical requirement, the majority of the electricity is used to maintain the cleanroom environment and generate and distribute ultra-pure water, nitrogen, and other gases about the facility.

Administrative solutions such as controlled staging times between clean and deposition steps as well as duplicate cleaning steps have also been implemented in order to improve device yield and performance. While serving their purpose, these solutions tend to create a bottleneck in the production line and can be wasteful of materials and energy. Cleaning processes currently involve a wet chemical treatment though there are numerous disadvantages to this method. Liquid phase treatments tend to react with the substrate in an isotropic manner, allowing for a cleaning step to adversely affect the geometry of a device. Because of this potential for inadvertently widening the device dimensions, an engineering safety margin has been built into the spacing of features. Elimination of duplicate cleans, or wet cleaning entirely would help to facilitate higher device density and potentially faster signal transfer rates across the chip. Shrinking dimensions have also begun to necessitate the elimination of liquid phase technologies because of wetting concerns for high aspect ratio features as well as pattern and structure collapse due to surface tension effects. With increasingly stringent processing and purity requirements, as well as additional concerns associated with the use of liquid phase technologies and environmental concerns, the industry is shifting from traditional liquid phase processes to gas phase ones [3, 9, 10]. Gas phase processing has numerous advantages including the possibility for point of use chemical generation, finer process control, and a tremendous decrease in the quantities of chemicals required. A change from liquid to gas phase processing can result in a decrease in chemical usage from by several orders of magnitude [3, 9].

With the increasing demands on particle requirements for cleanroom facilities, one possible solution is to eliminate the need for a cleanroom, and instead integrate a series of processing steps into a single ultra-clean vacuum cluster tool. The vacuum environment prevents both particle and oxidation contamination issues, and is a more appealing technology with the shift to larger wafers and single wafer processing [3, 9]. Reactive surfaces could be prepared and transferred between processing steps in a vacuum environment without compromising the quality of the surface [3, 9, 10]. If a method for protecting the surfaces during transfer between tools could be developed, the implementation of a gas phase cluster tool could ultimately lead to a decrease in the cleanroom requirement for the facility, as well as substantial energy savings. Such passivation is akin to the protection strategies used in chemical syntheses. Additionally, the ability to control the reactivity of a surface could be used as a basis for the atomic construction of a device, rather than the current subtractive method.

The goal for surface passivation is to develop a gas phase chemistry that protects the substrate against contamination and oxidation, but which can also be easily removed once its utility is finished. The passivation should consist of a single layer of atoms or molecules bound directly to the surface. Numerous surface chemistries have been explored, mostly involving the reaction of an organic molecule with monocrystalline silicon, though the vast majority of the research was performed in the liquid phase [11-14].

Currently, hydrogen passivation of silicon is used commercially in connection with fluorine-based chemistries to etch the silicon dioxide layers. The hydrogen layer provides only limited protection. The present process, described below, employs larger organic molecules, which provide greater amounts of steric protection for silicon surface bonds. The present gas phase process provides environmental benefits, improved protection against oxidation and contamination.

Thin film growth on a silicon surface currently requires heating the surface to a high enough temperature to induce reaction with a gas phase precursor molecule containing the film component. The present process, described below, deposits a single layer of halogen atoms using ultraviolet (UV) light. On silicon, the halogen layer activates the surface to do further chemistry. Exposure of a halogen-terminated surface to a gas phase molecule containing an alkoxy moiety (—OR, where R is an alkyl group), such as methanol, replaces the halogen atoms with alkoxy groups. Alkoxy termination provides greater steric protection for a silicon surface than hydrogen termination. Exposure of a halogen-terminated surface to water vapor replaces the halogen atoms with one layer of silicon dioxide terminated by hydroxyl groups and hydrogen atoms. This surface is a starting surface for deposition of a thin film containing a dielectric or metal. An example is given for the deposition of titanium to form a metal oxide. The halogen technique lowers the temperature of the subsequent reaction process, providing control to grow an interfacial film containing one atomic or molecular layer and making the process selective since the subsequent process reacts only where halogen atoms are adsorbed. This type of control is difficult or impossible with higher temperature processes.

Background Publications and Patents

Finstad and Muscat, “Atomic Layer Deposition of Silicon Nitride Barrier Layer for Self-Aligned Gate Stack,” published on line in 2004 describes the gas phase preparation of a chlorine layer on a silicon substrate, followed by preparation of an amine layer. This permits atomic layer deposition (ALD) of a silicon nitride diffusion barrier.

A paper by Thorsness and Muscat entitled “Interfacial Layer Formation on Silicon by Halogen Activation” described a room temperature Cl-UV process followed by reaction with H₂O or NH₃. This paper was published on the Internet in October 2005 in ECS proceedings.

“Method for removing organic contaminants from a semiconductor surface,” U.S. Pat. No. 6,551,409, discloses a method for removing organic contaminants from a semiconductor surface.

Pomarede, et al. U.S. Pat. No. 6,613,695, “Surface preparation prior to deposition,” discloses a surface treatment that provides surface moieties more readily susceptible to a subsequent deposition reaction, or more readily susceptible to further surface treatment prior to deposition by changing the surface termination of the substrate with a low temperature radical treatment.

Flaum et al., “Mechanisms of Halogen Chemisorption upon a Semiconductor Surface: I₂, Br₂, Cl₂, and C₆H₅Cl Chemisorption upon the Si(100) (2×1) Surface,” J. Phys. Chem. 1994, 98, 1719-1731 1719 discloses measurement of chemisorption probabilities (S) of monoenergetic I₂, Br₂, Cl₂, and C₆H₅Cl beams on the Si(100) (2×1) surface.

Kovtyukhova, et al., “Surface Sol-Gel Synthesis of Ultrathin Semiconductor Films,” Chem. Mater. 2000, 12, 383-389 disclose ultrathin films of ZnS, Mn-doped ZnS, ZnO, and SiO₂ were grown on silicon substrates using surface sol-gel reactions, and the growth of SiO₂ films from nonaqueous SiCl₄ on the same Si/SiOₓ substrates, which was regular from the first adsorption cycle, indicating a high density of nucleation sites.

Byatt, U.S. Pat. No. 4,375,125, “Method of passivating pn-junction in a semiconductor device” discloses the surface termination of a p-n junction of a semiconductor device that is passivated with semi-insulating material that is deposited on a thin layer of insulating material formed at the bared semiconductor surface by a chemical conversion treatment at a temperature above room temperature. The layer may be formed by oxidizing the semiconductor material of the body for example in dry oxygen between 300° C. and 500° C. or in an oxidizing liquid containing for example hydrogen peroxide or nitric acid at for example 80° C.

Chazalviel, “Surface Methoxylation as the key factor for the good performance of n-Si/methanol photochemical cells,” J. Electroanal. Chem. 233:37-48 (1987) discloses the treatment of silicon surfaces with methanol vapor to produce methoxy groups on the silicon surface.

Wei Cai, Zhang Lin, Todd Strother, Lloyd M. Smith, and Robert J. Hamers, “Chemical Modification and Patterning of Iodine-terminated Silicon Surfaces using Visible Light,” J. Phys. Chem. B, 106, 2656-2664 (2002), discloses the use of iodine as a photolabile passivating agent for photochemical modification of silicon surfaces. Measurements showed that iodine termination using iodine dissolved in benzene lead to Si surfaces exhibiting relatively higher iodine surface coverage and lower levels of carbon contamination. When exposed to 514 nm light in the presence of a suitable reactive molecule, such as an organic alkene, the surface iodine was removed and the reactive molecule links to the silicon surface.

Gstrein et al. “Effects of Interfacial Energetics on the Effective Surface Recombination Velocity of Si/Liquid Contacts,” J. Phys. Chem. B 2002, 106, 2950-2961, discloses that the immersion of Si into CH₃OH—I₂ solutions produces Si—OCH₃ bonds as well as a measurable surface coverage of iodine.

Royea et al. “Preparation of air-stable, low recombination velocity Si(111) surfaces through alkyl termination,” App. Phys. Lett. 77(13) (2000) 1988-1990, discloses a two-step, chlorination/alkylation procedure has used to convert the surface Si—H bonds on NH₄F_{(aq)} etched (111)-oriented Si wafers into Si-alkyl bonds of the form Si—CnH₂ₙ₊₁ (n>or =1). The electrical properties of such functionalized surfaces were investigated. Although the carrier recombination velocity of hydrogen-terminated Si(111) surfaces in contact with aqueous acids is less than 20 cm s⁻¹, this surface deteriorates within 30 min in an air ambient, yielding a high surface recombination velocity. In contrast, methylated Si (111) surfaces exhibited low surface recombination velocities.

Linford and Chidsey, “Surface Functionalization of Alkyl Monolayers by Free-Radical Activation: Gas-Phase Photochlorination with Cl₂,” Langmuir 2002, 18, 6217-6221, disclose the gas-phase photochlorination of methyl-terminated alkyl monolayers on silicon. This provides methods for the incorporation of various functional groups into simple alkyl monolayers by chlorine-radical activation. Monolayers prepared from 1-octadecene on Si(111) were exposed to Cl₂ with illumination at 350 nm. A fraction of the carbon atoms on the surface become singly chlorinated and a smaller fraction become doubly chlorinated, as measured by the chemically shifted components of the Cls X-ray photoelectron spectrum. The elemental composition of the resulting monolayers, film thickness, and contact angles were reported as a function of exposure.

Bansel et al., “Alkylation of Si Surfaces Using a Two-Step Halogenation/Grignard Route,” J. Am. Chem. Soc. 1996, 118, 7225-7226, discloses an alternative strategy to functionalize HF-etched Si surfaces involving halogenation and subsequent reaction with alkyl Grignard or alkyl lithium reagents. The H-terminated Si surface was first exposed to PCl₅ for 20-60 min at 80-100° C., in chlorobenzene with benzoyl peroxide as the radical initiator. Exposure of the chlorinated Si surface to alkyl-Li (RLi: R) (C₄H₉, C₆H₁₃, C₁₀H₂₁, C₁₈H₃₇) or alkyl-Grignard (RMgX: R)CH₃ C₂H₅, C₄H₉, C₅H₁₁, C₆H₁₃, C₁₀H₂₁, C₁₂H₂₅, C₁₈H₃₇; X=Br, Cl) reagents 13 for 30 min to 8 days (depending on the chain length of the alkyl group) at 80° C. produced the desired functionalized Si surfaces.

### BRIEF SUMMARY OF THE INVENTION

The following brief summary is not intended to include all features and aspects of the present invention, nor does it imply that the invention must include all features and aspects discussed in this summary.

A gas phase surface preparation process sequence has been developed to treat conducting, semiconducting, and insulating surfaces that replaces hydrogen atom termination, first with a halogen, then with another species, both steps being carried out at low temperature. In one aspect, the second reaction step is carried out to obtain hydroxyl (—OH) or methoxy termination (—OCH₃). The sequence consists of exposing the surface to be treated first to a halogen gas phase (e.g., I₂) irradiated by ultraviolet (UV) light. This is followed by exposure to a separate gas phase containing a molecule bearing a hydroxyl (OH) group. The UV-halogen step deposits halogen atoms (e.g., I) on the surface (e.g., Si), which are replaced by a hydroxy or alkoxy group when water, methanol, or other alcohol, is dosed.

Processes for selective deposition of thin metal films on conductors, semiconductors, and insulators that incorporate the surface treatments described above are also disclosed. One embodiment deposits a metal on a surface containing exposed hydroxyl groups. For example, a silicon dioxide (SiO₂) film grown thermally on a Si substrate can be patterned using standard lithographic and etching processes to expose regions of bare Si surface adjacent to regions covered by SiO₂. Treating this patterned surface first with a UV-halogen step deposits halogen (e.g., Cl) atoms preferentially on the exposed areas of Si, excluding the SiO₂ portions. A subsequent low temperature water step replaces the halogen atoms by hydroxyl groups. A final treatment with a metal halide (e.g., TiCl₄) deposits metal preferentially on Si in the form of a metal oxide (e.g., Si—O—Ti). Without the water treatment, the halogen-terminated surface blocks the reaction of the metal halide. By reacting the remaining halogen atoms attached to the metal atom with cycles of water and metal halide, a metal oxide film can be deposited on Si selectively, excluding the SiO₂ film. This process self-aligns the deposition of a metal oxide film on Si and reuses the initial pattern, saving process steps, reducing environmental impact, and lowering processing costs.

These processes may advantageously be carried out below 200° C., and are carried out in the gas phase, either at low pressure or in an inert atmosphere, save for the reactants.

Thus, in one aspect, the present invention comprises a process for manipulating surface termination, as that term is commonly understood in the art. It is useful on a substrate having hydrogen atom termination, such as silicon, glass, carbon, quartz and the like. The substrate may be a semiconductor material, such as a Group IV material, or a Group III/V material.

The semiconductor material may further be selected from a preferred group consisting of Si, germanium, and InSb. The halogen may be any halogen, or, specifically, chlorine or iodine. The ultraviolet light used during halogen attachment is between 190 and 450 nm.

The passivation layer is intended to be at least partially removed in a subsequent step. This may be done by heating. Removal of said passivation layer is typically followed by a step of applying directly to a pristine substrate a metal, such as a gate electrode, or a metal oxide. Useful non-refractory gate metals include platinum and ruthenium. An exemplary refractory gate metal is tungsten. Other suitable metals are titanium, cobalt, zirconium, hafnium, and alloys and compounds, such as oxides, comprising these metals.

The present gas phase UV-halogen and R—OH processes may advantageously be carried out at relatively low temperatures, e.g., between 25° C. and 75° C. The metallization process can be carried out below 200° C. These processes are carried out in an inert atmosphere, such as a vacuum, and with gaseous components present at about 10 Torr. One may also use an inert gas selected from one or more of nitrogen, helium, neon, argon, krypton, xenon, or carbon dioxide.

The process may comprise a first step of selectively exposing a substrate to a halogen gas while the surface is also being irradiated by ultraviolet light to form a halogen surface layer on an exposed portion; a second step of exposing said halogen surface layer to an aqueous gas, such as steam or water bearing gas. This causes formation of hydroxyl groups linked to the silicon oxide monolayer. In the next step, a metal halide, reacts with the hydroxyl groups, whereby metal is deposited only on exposed portions of the surface of the substrate. The metal halide is linked through a monolayer of silicon oxide to the substrate.

The present methods, which comprise the use of hydrogen terminated silicon, may be combined with known lithographic methods, such as creating a silicon dioxide layer and then selectively removing portions to expose hydrogen terminated silicon. Selective removal may be accomplished by HF etch, as described in U.S. Pat. No. 6,656,804, “Semiconductor device and production method thereof,” issued on Dec. 2, 2003 and hereby incorporated by reference. Another technique is disclosed in “Method of removing silicon oxide from a surface of a substrate,” U.S. Pat. No. 6,806,202, issued on Oct. 19, 2004 and also incorporated by reference. This process may also include the step of heating the substrate above 300 degrees C. to remove residual halogen.

### BRIEF DESCRIPTION OF THE DRAWINGS

FIG. 1 is a schematic drawing of a deposition process according to the present invention, wherein FIG. 1A represents a gas phase alkoxy passivation process, and FIG. 1B represents a gas phase metallization process;

FIG. 2 is a graph showing XPS carbon coverage data for Si(100) samples aged under dark ambient conditions for 11.2 days. Standard preparation methods as described above were used. Methanol exposure was performed at 120° C.;

FIG. 3 is a graph showing XPS oxygen coverage data for Si(100) samples aged under dark ambient conditions for 11.2 days. Standard preparation methods as described above were used. Methanol exposure was performed at 120° C.;

FIG. 4 is a graph showing XPS iodine coverage data for Si(100) samples aged under dark ambient conditions for 11.2 days. Standard preparation methods as described above were used. Methanol exposure was performed at 120° C.;

FIG. 5 is a graph showing CV Data for various Si(100) samples (DHF cleaned, MeOH, UV-I2-MeOH) aged under dark ambient conditions for 11.2 days as compared with a theoretical model, with curves from left to right corresponding to labels from top to bottom, i.e. ideal surface is rightmost;

FIG. 6 is an XPS spectrum of a methoxy carbon layer and a UV iodine layer preceding it, the curve with the higher peak is post methanol exposure;

FIG. 7 is a graph of O and CL coverage showing the ratio of O added to Cl removed after water vapor exposure, with both high H₂O exposure data points above 0.8 change in O coverage;

FIG. 8 shows XPS data after addition of UV/Cl₂, 60 min H₂O, and 30 min H₂O;

FIG. 9 is a graph of XPS data before and after TiCl₄ exposure of a H/Si(100) surface (top) and a UVCl₂+H₂O exposure surface (bottom).

### DETAILED DESCRIPTION OF THE PREFERRED EMBODIMENT

Introduction

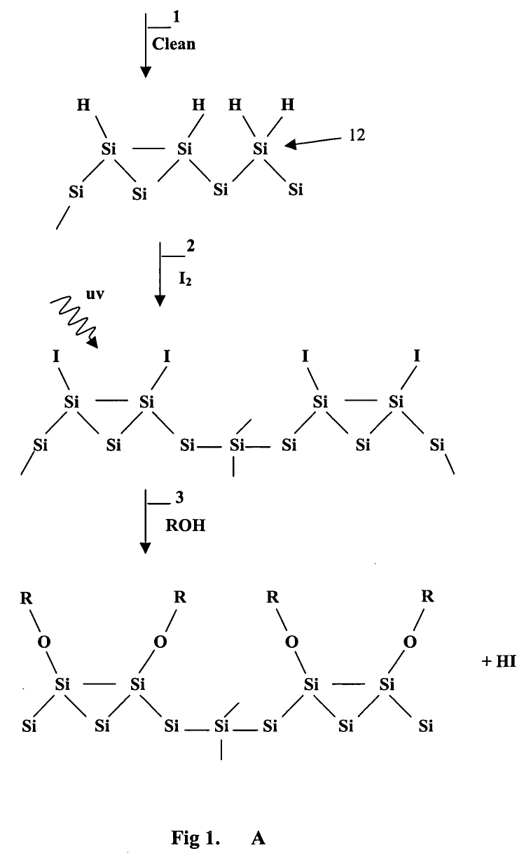

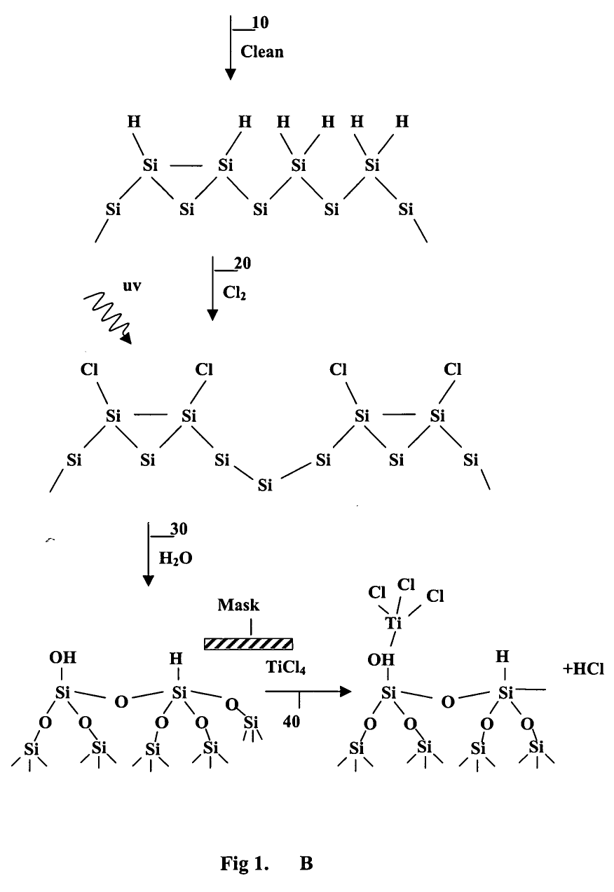

FIG. 1 shows a general schematic of the present process.

The schematic in FIG. 1A describes a representative process in which a silicon substrate is first prepared by removal of any oxide or contaminants, in step 1. This would typically be done by standard cleaning chemistries for silicon substrates, such as RCA 1, RCA 2, and dilute aqueous HF, which leaves any dangling bonds passivated with hydrogen atom termination. Next, in step 2, a halogen is reacted with UV light to replace the H. The halogen, in this case I₂, is in the gas phase and the UV light shines on the gas and the Si surface during the reaction. The resultant halogen surface has been shown (by AFM) to be a smooth, complete monolayer, without causing any etching, indentations or other roughness in the Si substrate. The UV halogen process yields a smooth monolayer below 200° C., below 10 Torr of halogen, and in exposure times of less than 5 min. The gaseous halogen, e.g., I₂, is added in the absence of H₂O or O₂, preferably in a vacuum, or, alternatively in an inert atmosphere, such as nitrogen, helium or the like. The iodine may be reacted with selected portions of the substrate by masking the substrate or coating it with an oxide film not containing hydroxyl groups, using standard silicon lithographic techniques. For example, part of the silicon substrate may be masked to prevent UV and halogen exposure, or it may be covered with a resist that will coat the Si—H surface and prevent the Si—Cl (halogen) reaction. Alternatively, the passivation layer may be applied (step 3 below) to the entire surface. Step 3 is the addition of an alcohol-containing compound (ROH). A single layer of silicon oxide is formed that is terminated with alkyl groups or, equivalently, the silicon surface is terminated with alkoxy groups (Si—O—R). The halogen is hydrolyzed from the surface.

The hydrogen-terminated silicon 12 may be adjacent to a layer of silicon dioxide, and may have been formed by lithographic patterning of the SiO₂ layer. For example, a layer of photoresist (typically a chemical that hardens when exposed to light) may be applied to a silicon wafer. The photoresist is selectively hardened by illuminating it in specific places. For this purpose a transparent plate with patterns printed on it, a mask, is used together with an illumination source to shine light on specific parts of the photoresist. Then, the photoresist that was not exposed to light and the layer underneath is etched away with a chemical treatment.

Referring now to FIG. 1B, a cleaning step 10 is carried out as described in connection with FIG. 1A. Next, in step 20, a halogen (e.g., Cl₂) gas and UV light are reacted as in step 2 of FIG. 1A. Then, in step 30, the halogen-terminated Si is reacted with H₂O vapor. The water vapor causes a hydroxyl-terminated silicon oxide monolayer to form on the surface. The OH groups form a reactive surface for subsequent addition in step 40, of a metal halogen (e.g., TiCl₄). Addition of the metal halide (TiCl₄) is carried out to form a metal oxide, plus an acid.

Definitions

The term “semiconductor” is used in a conventional sense, and is intended to mean materials with a resistivity between about 1<r<10⁸ Ohm-cm. Such materials may include elemental semiconductors where each atom is of the same type such as Ge, Si. These atoms are bound together by covalent bonds, so that each atom shares an electron with its nearest neighbor, forming strong bonds. They may also include compound semiconductors, which are made of two or more elements. Common examples are GaAs or InP. These compound semiconductors belong to the III-V semiconductors so called because first and second elements can be found in group III and group V of the periodic table respectively. Ternary semiconductors are formed by the addition of a small quantity of a third element to the mixture, for example AlₓGa₁₋ₓAs. The subscript x refers to the alloy content of the material, what proportion of the material is added and what proportion is replaced by the alloy material. The addition of alloys to semiconductors can be extended to include quaternary materials such as GaₓIn₍₁₋ₓ₎As_{y}P_{(1-y)} or GaInNAs and even quinternary materials such as GaInNAsSb. Also included are extrinsic semiconductors, which can be formed from an intrinsic semiconductor by added impurity atoms to the crystal in a process known as doping. For example, since silicon belongs to group IV of the periodic table, it has four valence electrons. In the crystal form, each atom shares an electron with a neighboring atom. In this state it is an intrinsic semiconductor. B, Al, In, Ga all have three valence electrons. When a small proportion of these atoms, (less than 1 in 10⁶), is incorporated into the crystal the dopant atom has an insufficient number of bonds to share bonds with the surrounding silicon atoms. Further examples of semiconductor materials contemplated by the present process include SiGe, Ge, InP, InAs, InSb, InAlSb, InGaAs, and GaSb.

The term “halogen” is used in its conventional sense and means the elements in Group 17 (old-style: VII or VIIA) of the periodic table: fluorine (F), chlorine (Cl), bromine (Br), iodine (I), and astatine (At). The above list is in descending order of electronegativity, which makes the halogen more reactive toward H atoms on the incoming precursor. A larger size halogen makes the product hydrogen halide more volatile, so is a better leaving group and more easily removed from the surface. Also the size of the halogen is important to the other materials mentioned since these atoms have different sizes relative to silicon.

The term “lower alkyl” is used herein to refer to a branched or unbranched, saturated or unsaturated acyclic hydrocarbon radical. Suitable alkyl radicals include, for example, methyl, ethyl, n-propyl, i-propyl, 2-propenyl (or allyl), vinyl, n-butyl, t-butyl, i-butyl (or 2-methylpropyl), etc. In particular embodiments, alkyls have between 1 and 20 carbon atoms, between 1 and 10 carbon atoms or between 1 and 3 carbon atoms. The lower alkyl may be a substituted alkyl or alkoxy, as further defined below.

The term “substituted alkyl” as used above refers to an alkyl as just described in which one or more hydrogen atom to any carbon of the alkyl is replaced by another group such as a halogen, aryl, substituted aryl, cycloalkyl, substituted cycloalkyl, and combinations thereof. Suitable substituted alkyls include, for example, benzyl, trifluoromethyl and the like.

The term “alkoxy” as used above refers to the —OZ¹ radical, where Z¹ is selected from the group consisting of alkyl, substituted alkyl, cycloalkyl, substituted cycloalkyl, heterocylcoalkyl, substituted heterocycloalkyl, silyl groups and combinations thereof as described herein. Suitable alkoxy radicals include, for example, methoxy, ethoxy, benzyloxy, t-butoxy, etc. A related term is “aryloxy” where Z¹ is selected from the group consisting of aryl, substituted aryl, heteroaryl, substituted heteroaryl, and combinations thereof. Examples of suitable aryloxy radicals include phenoxy, substituted phenoxy, 2-pyridinoxy, 8-quinalinoxy and the like.

The term “XPS,” as is known in the art, refers to x-ray Photoelectron Spectroscopy (XPS). In the experiments below, there will be a characteristic binding energy associated with each core atomic orbital, i.e. each element will give rise to a characteristic set of peaks in the photoelectron spectrum at kinetic energies determined by the photon energy and the respective binding energies. The presence of peaks (arbitrary counts) at particular energies (eV, X-axis) therefore indicates the presence of a specific element in the sample under study—furthermore, the intensity of the peaks is related to the concentration of the element within the sampled region. Thus, the technique provides a quantitative analysis of the surface composition and is sometimes known by the alternative acronym, ESCA (Electron Spectroscopy for Chemical Analysis). The emitted photoelectrons will therefore have kinetic energies in the range of ca. 0-1250 eV or 0-1480 eV. Since such electrons have very short mean free paths in solids, the technique is necessarily surface sensitive.

The term “passivation layer” is used in its conventional sense, and refers to a layer that is applied to a reactive surface to protect the surface from unwanted reactions with surrounding materials; such a layer is intended to be removed for further processing.

The term “activation layer” is used to mean a layer that when deposited on a surface increases the reactivity of a subsequent reaction by lowering the activation energy barrier.

The term “Group IV material” is used in its conventional sense to mean materials comprising Group IV elements, which include C, Si, Ge, Sn and Pb.

The term “Group III/V material” is used in its conventional sense to mean Group III elements, which include B, Al, Ga, In and Ti; Group V elements include N, P, As, Sb and Bi; A Group III-V material may comprise at least one member from Group III and at least one member from Group V, for example GaAs, GaP, GaAsP, InAs, InP, GaN, AlGaAs, or InAsP.

The term “ultraviolet light” is used in its conventional sense to mean light having a wavelength in the range of about 190 to 450 nm, although the lamps that are commonly used are in the middle UV range, about 280-320 nm. UV lamps having a power of 15 to 25 watts are commonly used, and these should be at a distance of about 1-3 inches being preferable. In the experiments described below, a 1000 W xenon arc lamp that puts out light from 190 nm to the mid infrared was used, although a infrared filter was inserted between the lamp and sample to avoid uncontrolled sample heating. The most important region is the UV from 190 to 450 nm.

Described below is a gas phase process sequence for treating a substrate, which may be a semiconducting surface (e.g., Si) by replacing hydrogen atom termination with, in the first aspect, hydroxyl (—OH) or methoxy termination (—OCH₃). In this first aspect, the resultant layer is useful as an activation layer for the deposition of a subsequent film, and in the second aspect for use as an alternative passivation layer to hydrogen.

Overall, the inventive sequence involves exposing the surface to be treated first to a halogen gas phase (e.g., I₂) irradiated by ultraviolet (UV) light followed by exposure to a separate gas phase containing a molecule bearing a hydroxyl (—OH) group, namely water or R—OH. The H₂O treatment yields an SiOH monolayer that acts as an activation layer for subsequent deposition of a metal such as TiCl₄(g) (vapor phase). The R—OH treatment yields a passivation layer that is later removed by e.g., heating.

Hydroxyl termination of silicon is an ideal starting surface for atomic layer deposition of a range of materials including high dielectric constant films, which will form the gates of future generations of transistors in microelectronic devices. Hydroxyl surface termination of silicon is also useful to improve the nucleation and continuity of thin films grown using atomic layer deposition. Current processes have long incubation times and produce uneven film growth.

Thus, a pre-treatment step enhances the selectivity of atomic layer deposition of metals on conductor or semiconductor surfaces of a substrate (e.g., silicon, copper, etc.) and inhibits nucleation and growth on an insulator surface (e.g., SiO₂, carbon-doped oxide, etc.). The pre-treatment steps include exposure of clean insulator and conductor or semiconductor surfaces to a gas phase containing a halogen (e.g., Cl₂ or I₂) irradiated by ultraviolet (UV) light followed by water vapor exposure at low temperature to avoid forming hydroxyl groups on the insulator material. That is, the insulator material may be SiO₂, and the low temperature would prevent formation of hydroxyl groups on the surface of this layer. The halogen atoms stick preferentially to the conductor or semiconductor surfaces terminated by hydroxyl groups and not to the oxide layer. Deposition of the metal layer is carried out using a metal halogen precursor. For example, exposing SiO₂ and Si surfaces simultaneously to a UV-Cl₂ pre-treatment step deposits Cl atoms preferentially on Si. The Cl atom layer is replaced by exposure to water vapor forming OH groups on the surface. Deposition of a titanium metal layer using TiCl₄ occurs on SiOH (silanol) surface sites but is blocked on SiO₂ since there are no OH groups present. Deposition of the metal precursor below 200° C. ensures that it does not react or decompose in the gas phase and deposit spontaneously on all surfaces. If residual Cl is present on the surface of Si it can be thermally desorbed at temperatures in vacuum above 300° C.

This process has particular application in depositing metal interconnect layers for microelectronic device fabrication. One embodiment replaces a halogen layer at the bottom of a via by a reactive group such as OH that selectively nucleates deposition of a metal layer relative to the neighboring dielectric surfaces. Another embodiment of the process uses a halogen layer at the bottom of a via to block the reaction of a metal halide there. Use of the halogen as a blocking layer could eliminate the barrier or liner layer from the contact point at the bottom of a via, which would (1) reduce the resistance of the interconnection and (2) eliminate voids produced by electromigration at the interface between the barrier and copper. This selective deposition process makes use of an intentionally deposited atom, in this case a halogen, to block the adsorption of the deposition precursor molecule. Previous selective deposition processes tried to take advantage of sticking probability differences on surfaces with different chemical properties but were unsuccessful since the selectivity was not high enough. Addition of the halogen to silicon or copper surfaces increases the selectivity difference relative to oxide to make this an industrially viable process. Moreover, past technologies have tried to enhance the selectivity of a metal on a conductor or semiconductor surface relative to an insulating surface.

Turning now to the R—OH process, alkoxy, e.g., methoxy termination of a silicon surface is a more stable passivation layer than hydrogen, which is currently used in microelectronic device fabrication. Methoxy termination of silicon forms a passivation layer that suppresses growth of native oxide and adsorption of organics better than a hydrogen-terminated surface and that can be removed from the surface by heating without leaving any significant contamination. Gas phase sequences to achieve these terminations on silicon would allow them to be integrated with succeeding deposition steps in a clustered processing tool. Process integration is necessary to achieve reproducible atomic layer growth of films that are needed for future generations of microelectronic devices.

Methoxy surface termination by the above outlined process sequence has been demonstrated.

Experimental Methods

Experiments were performed on the Research Cluster Apparatus (RCA) at the University of Arizona. The RCA is a collection of gas phase reactors and two analysis chambers connected by a high vacuum transfer tube, which allows samples to be processed without exposure to air [15]. One of the two analysis chambers includes x-ray photoelectron spectroscopy (XPS) and Auger electron spectroscopy (AES) surface analysis tools. Temperature programmed reaction spectroscopy (TPRS) studies are performed in the other. Among the reactor modules is the photochemistry reactor where samples were exposed to UV-12 and UV-Cl₂, and the solvent reactor where samples were exposed to methanol and water vapor. The in-situ capabilities provided the means to process and characterize a surface without exposing it to ambient conditions. Gas phase surface preparation steps enabled Si to be terminated with a specific atom or functional group by virtue of vacuum isolation (10⁻⁹ Torr) between modules. This capability allowed a study of how ambient exposure affects the level of contamination and oxidation on the surface.

### EXAMPLE 1

### Methoxy Barrier

Removal of Oxide Layer

Hydrogen-terminated Si(100) samples (p-type 38-63 Ohm-cm, 14 by 15 mm) were prepared by a degreasing step using an isopropyl alcohol wipe followed by a 10 minute treatment in a Class 10 grade 1:1 96% H₂SO₄: 30% H₂O₂ solution followed by an ultra-pure water rinse to remove organic contamination and chemically oxidize the surface. The resulting oxide layer was then removed by a 5-minute treatment in a 1:100 49% HF:H₂O solution. Samples were rinsed in ultra-pure water and blown dry under a stream of N₂ gas. Samples were then mounted onto stainless steel transfer pucks and loaded into the vacuum system.

Methoxy Passivation (with and without I₂)

Methoxy passivation was prepared by two different methods; direct adsorption of methanol on hydrogen terminated silicon, or by a two-step iodination followed by the substitution of methanol onto the surface. Iodine terminated samples were prepared with 10 minute exposures to 0.5% I₂ (Aldrich Chemical Company Inc., 99.99+%) in N₂ mixtures at 100 Torr and 25° C. under illumination of a 1000 W Xe arc lamp equipped with an infrared filter to limit sample heating. Methoxy terminated samples were prepared from either hydrogen or iodine terminated samples with 30 minute exposures to 25% methanol (MeOH) (Sigma Aldrich, anhydrous, 99.8%) in N₂ mixtures at 200 Torr and 25-135° C. XPS was performed after both iodine and methoxy termination. Surface coverage was calculated from XPS peak areas using a calibration curve prepared for Cu on silicon and the appropriate atomic sensitivity factors [16, 17]. The three surfaces being investigated will henceforth be referred to as hydrogen-terminated, direct-methoxy, and two-step methoxy.

In order to demonstrate the passivation capability of methoxy-termination, samples were prepared under vacuum in the RCA system, and then were exposed to ambient conditions in the absence of light over time. XPS spectra were collected periodically, and it was assumed that no change occurred on the samples while in vacuum in the RCA system for analysis. Following the aging period, a wet thermal oxide (˜3000 Å) was grown, and a metal insulator semiconductor (MIS) capacitor structure was fabricated. The backside oxide on wafer samples was removed using a BOE solution while photoresist was used to protect the device features. Substrate contact (100 nm thick Au) and gate metal (Al 100 nm thick and 0.1 or 0.2 cm diameter metal) were deposited using either a thermal evaporator for the aluminum, or an electron-beam evaporator (BOC Edwards E-beam Evaporator Auto 306) and annealed at 450° C. for 30 minutes in an N₂ ambient.

C-V curves were measured at 1 MHz with a bias from −40V to +40V using an Agilent 4284A precision LCR meter at ambient conditions. Electrical measurements were conducted on both aged samples and freshly prepared samples. All measurements were carried out in a light tight box using a micromanipulator probe with a vacuum chuck. The curves in the depletion region were used to calculate the interface trap density for the Si/SiO₂ interface.

Results

Methoxy passivation has been shown to protect the silicon surface against contamination and oxidation better than the current method of hydrogen termination. The organic functionality was observed to desorb cleanly from the surface upon heating, requiring no additional removal step before oxidation. Capacitance-voltage measurements indicate that the highest quality interface was achieved after exposure to ambient conditions over time by passivation using a two-step UV-iodine/MeOH treatment (0.5% UV-I₂ in N₂ at 100 Torr and 25° C. for 10 minutes and 25% MeOH in N₂ at 200 Torr and 120° C. for 30 minutes).

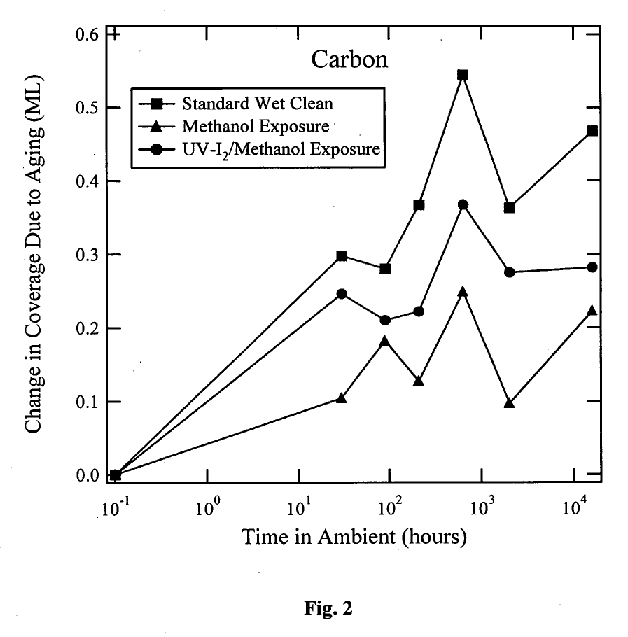

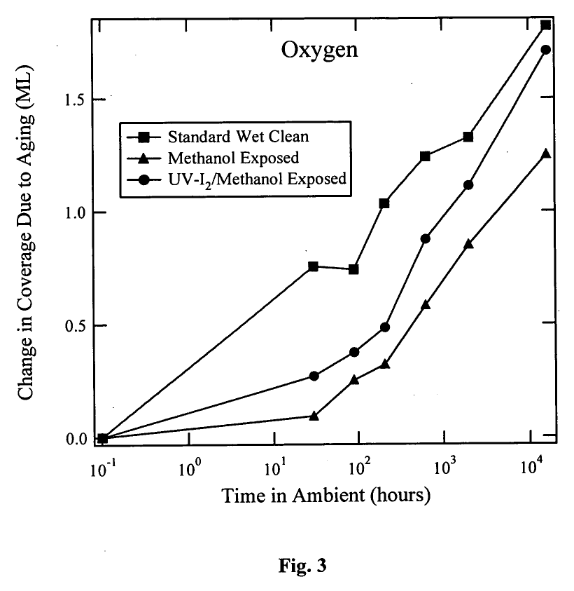

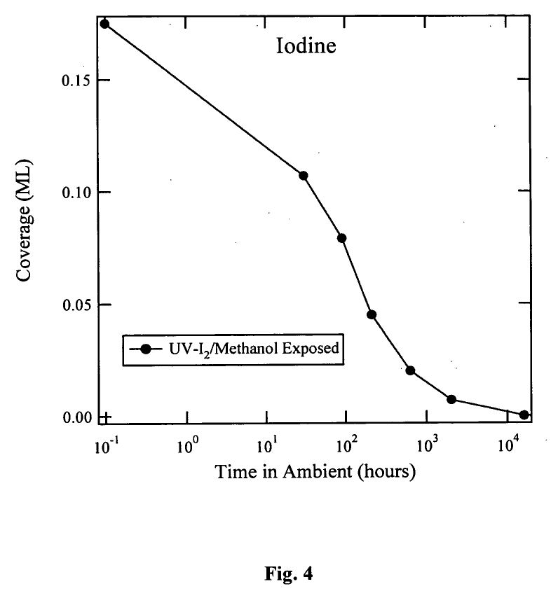

The passivation capability of various Si(100) surfaces was examined as a function of time. Trends in carbon, oxygen, and iodine coverages were obtained over time. Experiments were performed over both short and long timescales, with the longest experiment providing data over the course of several weeks. FIGS. 2 and 3 show the change in carbon and oxygen coverages as a function of time, relative to the initial coverages present at the start of the aging experiment. The trends in the carbon and oxygen coverage were that of a logarithmic increase, leveling off with time. FIG. 4 provides a graph of absolute iodine coverage as a function of time, showing the exponential decrease in surface iodine as it reacts with air.

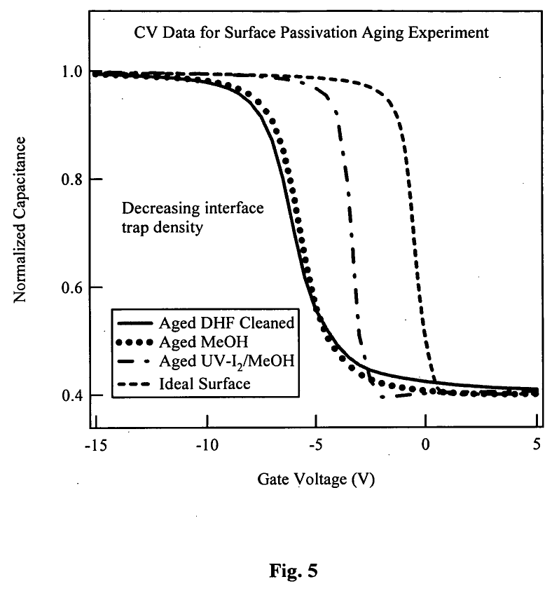

At the conclusion of an aging experiment, MIS structures were constructed and the interface quality of the Si/SiO₂ layers was examined using C-V electrical measurements. FIG. 5 shows a set of C-V curves for a hydrogen-terminated sample, the direct-exposure, and the two-step methoxy sample. Methoxy-passivated samples were prepared by methanol dosing at 120° C. on both initially hydrogen and iodine terminated samples as described above. The experimental data was also compared to a model C-V curve generated from theory [18]. The only non-ideality considered in the preparation of the model was the metal-semiconductor work-function, allowing for the calculation of various parameters such as the interface trap density from a comparison of the experimental and theoretical curves. The data shows normalized capacitance (C/Cₒ) as a function of the applied gate voltage.

A parametric investigation indicated that the optimal processing conditions for the largest saturation coverage of methoxy surface groups were at either 65° C. or 120° C. (25% MeOH in N₂ at 200 Torr for 30 minutes) for methanol exposure on both hydrogen and iodine terminated surfaces. Surfaces prepared using a two-step exposure of methanol on an iodine-terminated surface resulted in higher total carbon and oxygen coverages than for direct methanol exposure on a hydrogen-terminated surface.

XPS coverage data from the aging experiments indicated that the methoxy-passivated surfaces experienced significantly lower incident carbon contamination than an analogous hydrogen-terminated sample, regardless of the amount of time spent in air. The largest initial increase in carbon contamination was observed in the first 30 minutes of ambient exposure, and further aging occurred with relatively little additional contamination. This large initial increase suggests that unless wafers can be transferred directly from a cleaning station into a deposition chamber, limited staging times may not significantly affect the amount of contamination that is present on the wafers. Methoxy passivation, however, lowers the amount of adventitious carbon contamination by approximately 60%, offering a significant improvement in performance without placing restrictions on the flow of materials through the factory.

Prepared samples were exposed to ambient conditions over time, and it was found that methoxy passivation decreased carbon contamination and native oxidation as compared to a wet cleaned surface. 30-60% reduction in carbon contamination over time was observed. There was 50-70% less oxidation within 10 hours, and 10-35% less oxidation after 10 days.

As shown in FIG. 5, the UV-I₂/MeOH treated sample exhibited CV properties superior to a MeOh treated sample without halogen treatment. The results are summarized in the Table below. These results indicate that interface traps result in a spreading of the depletion region in a C-V curve, and that methoxy-termination maintained a higher Si/SiO₂ interface quality, despite extended periods of exposure to ambient contamination. This performance is in the range of industrial device defect densities (10⁹-10¹¹ cm⁻²).

C-V Data On H-terminated, MeOH only, and UV-I₂/MeOH
treated samples
Summary of Electrical Measurement Results

| | | Dᵢₜ % Change | | Qₒₓ % Change |
|---|---|---|---|---|
| | Dᵢₜ | compared to | Qₒₓ | compared to |
| | (cm⁻² eV⁻¹) | I₂/MeOH | (cm⁻²) | I₂/MeOH |
| H terminated | 1.9E+11 | 224% | 3.1E+11 | 98% |
| MeOH-only | 6.7E+10 | 16% | 2.8E+11 | 79% |
| I₂/MeOH | 5.8E+10 | 0% | 1.6E+11 | 0% |

Lower rates of oxidation were also observed for the methoxy-passivated versus the hydrogen-terminated samples. The growth of native oxide occurs by reaction of the surface with oxygen and water in the atmosphere [19]. Oxidation is a diffusion-limited process, with the lower reaction rates from methoxy-passivated samples indicating a longer and more difficult pathway over which species must diffuse before reacting. These data support the theory that methoxy groups are able to not only satisfy otherwise dangling surface bonds, but also to help distance the silicon from direct contact with the atmosphere. No distinct trend in the XPS coverage data for either carbon or oxygen was observed between the methoxy surfaces prepared on hydrogen versus iodine terminated substrates.

Analysis of the C-V data indicated no significant difference in interface quality between the two methoxy-passivated surfaces within the first two hours of ambient exposure. Interface quality can be qualitatively measured through an analysis of the slope of the depletion region on a C-V curve and quantitatively by the interface trap density in a device. Decreased interface quality results in a spreading of the depletion region of the C-V curve, and thus an increased interface trap density. The electrical testing demonstrated that both of the methoxy-passivated surfaces resulted in a higher quality interface than the hydrogen-terminated sample. An examination of methoxy-passivated samples prepared at both 65° C. and 120° C. for the direct and the two-step methods was done in order to better quantify an optimal processing strategy. Methanol dosing temperature appeared to have no significant effect on the samples prepared by direct methanol exposure. Temperature was observed to have a significant effect for those samples prepared by the two-step method. In this case the surface prepared at 120° C. displayed significantly higher Si/SiO₂ interface quality, on par with the direct methanol exposure samples and with a theoretical model of an “ideal” device.

While no significant difference was observed between the two methoxy-passivation strategies for aging performed on a short timescale, electrical data collected after longer periods of time indicated a significant change in the resulting interface quality. The sample prepared by the two-step method maintained an interface quality on par with the theoretical model while a significant decrease in interface quality was seen for the other samples.

Dissociative adsorption of methanol may be represented as
CH₃OH+Si—H→Si—OCH₃+H₂

In the case of substitutive reaction of methanol on iodine terminated surface, iodine provides a more reactive substrate and has the potential for selective adsorption for additive processing
CH₃OH+Si—I→Si—OCH₃+HI

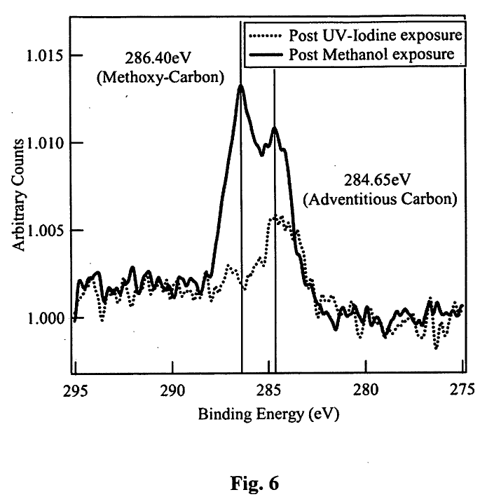

The above described methoxy termination was detected via a shift in the carbon (1s) peak of the XPS spectrum as shown in FIG. 6. The XPS peak at a binding energy of 286.40 eV appeared after dosing a I-terminated Si surface with methanol. This peak is assigned to the C in methoxy bound to a Si surface (Si—OCH₃), since it was distinguished from the C at a binding energy of 284.65 eV due to adventitious or residual carbon on the surface. The peak shift to higher binding energy is consistent with the C in the methoxy (Si—OCH₃) bound to a more electronegative O atom than residual carbon bound directly to Si (Si—C). Further experiments showed that optimal dosing temperatures for methanol were 65 and 120° C., without iodine and 120° C. with iodine. That is, the methanol reacted with a Si surface without the presence of the halogen, but resulted in a poorer coverage.

Temperature had no significant effect on C coverage in the range considered (25° C.-135° C.). The average total carbon and oxygen coverages observed following an iodine-methanol treatment were ˜0.8 ML on Si(100) and 0.7 ML on Si(111). While good agreement between carbon and oxygen coverages was seen for the iodine-methanol treatment, thermal-methanol exposure resulted in an average carbon coverage of 0.6 ML and oxygen coverage of 0.4 ML on Si(100) and 0.7 ML and 0.6 ML on Si(111). These values are within the range of expected values for saturation of the silicon surface based on a geometric packing calculation utilizing atomic and ionic radii and Tolman's cone angle.

### EXAMPLE 2

Thermal and UV-Initiated Adsorption of Iodine on Si(100) and Si(111)

The photochemistry reactor module on the RCA was used to expose samples to iodine with and without UV light. The in situ gas phase surface preparation capability of the RCA system enables samples to be terminated with specific functional groups and subsequently characterized without exposure to ambient, by virtue of vacuum isolation (10⁻⁹ Torr) between reactor modules. The purpose of this investigation was to compare UV activated deposition of a halogen atom to thermal deposition. The UV light illuminated both the halogen (e.g., I₂) gas phase and the sample surface. Two different crystal faces of Si were studied.

Sample Preparation

All samples were degreased using an isopropyl alcohol wipe and then treated in class 10 grade 1:1 96% H₂SO₄: 30% H₂O₂ solution for 10 minutes to remove organics and rinsed with ultra-pure water. The oxide layer was removed from Si(100) samples (p-type 38-63 ohm-cm) by a 5-minute treatment in 1:100 49% HF:H₂O solution. The oxide was stripped from Si(111) samples (p-type>100 ohm-cm) using a 5 minute etch in a 6:1 SEMI grade 40% NH4F:49% HF (BOE) solution with SAS surfactant. Samples were rinsed after liquid phase cleaning in ultra-pure water and blown dry under a stream of N₂ gas. These liquid phase cleaning procedures produced hydrogen-terminated samples, which was verified by FTIR. Samples (14×15 mm) were mounted on stainless steel transfer pucks after cleaning and loaded into the vacuum system of the RCA.

Iodine Adsorption

Iodine terminated samples were prepared with 10 min exposures of hydrogen terminated silicon samples to 0.5% 12 (Aldrich Chemical Company Inc., 99.99+%) in N₂ mixtures at 100 Torr and 25-200° C. Some exposures were performed under illumination by a 1000 W Xe arc lamp equipped with an infrared filter to limit sample heating. To identify the UV wavelengths necessary for iodine adsorption, some samples were processed with a monochromator placed between the light source and the reactor, allowing the samples to be exposed to only a narrow range of wavelengths at a time. XPS was performed on samples both before and after iodine exposure. Surface coverage was calculated using XPS peak areas based on a calibration curve prepared for Cu on silicon and atomic sensitivity factors [1-3]. A series of XPS spectra were measured for a clean surface as well as samples with high and low iodine coverages.

Results

The photonic and thermal activation of gas phase adsorption of iodine on Si(100) and Si(111) were examined. Trends in iodine adsorption as a function of dosing temperature, gas exposure, and UV wavelength were obtained. Within the limitations of experimental error, it was determined that UV activated deposition produced a saturation coverage of 0.29±0.02 ML on Si surfaces and thermal activation produced 0.22±0.02 ML.

XPS data were obtained for UV-enhanced iodine adsorption on Si(100) and Si(111) as a function of the wavelength of light. A plot of light absorbance versus wavelength for I₂ showed a maximum coverage at a UV wavelength of 500 nm. This wavelength of light corresponds to the maximum absorbance of diatomic iodine (I₂). Examination of the data from the two crystal planes indicates that there is no significant difference in the reactivity of UV-enhanced iodine. Si(100) and Si(111) have different surface bonding configurations, bond and energy densities, and known differences in reactivity towards some chemistries, but no effect was observed in this instance. Additionally, were the UV-light to play a role in activating the surface towards reaction, an effect near 330 nm would be expected. 330 nm corresponds to the absorbance of Si—H bonds. The creation of electron-hole pairs in the substrate was also insignificant because there was no trend in adsorption with the energy of the light. Based on these observations we propose a light-activated reaction mechanism whereby molecular iodine dissociates to form iodine radicals or atoms that react with a silicon surface.

XPS spectra of the iodine 3d_{5/2} and 3d_{3/2} peaks were deconvoluted for low and high iodine coverages on Si(100) (data not shown). Binding energies were referenced to the Si 2p peak at 99.54 eV. A spectrum measured on the clean surface after a standard wet clean sequence showed no I coverage. A spectrum measured in the low (0.07 ML) I coverage range achieved by a 10 min exposure at 25° C. with 200 nm UV-light showed small peaks at the expected binding energies. A spectrum after exposure with 500 nm UV light showed a significant increase in coverage to 0.28 ML or the maximum coverage with the same gas exposure.

The adsorption behavior of iodine, in the absence of light, as a function of temperature was also investigated. Data for a Langmuir-type analysis of the adsorption reaction was collected at two different dosing pressures, 100 Torr and 1 Torr, as well as on two different substrates, Si(100) and Si(111), over a temperature range of 25-200° C. No significant difference was observed between the two different silicon surfaces. Pressure also appeared to have little effect on the adsorption reaction. A trend of very low iodine coverage (0.05-0.10 ML) was observed at low processing temperatures with a sharp increase in coverage observed above 130° C. Maximum saturation appears to be reached in the range of 150-200° C., resulting in slightly lower coverages as compared to the UV-enhanced iodine adsorption.

A Langmuir-type analysis of the data was performed (data not shown). In a Langmuir isotherm, the ΔH for the reaction can be calculated from the slope of the line. Analysis of the data using this method shows a discontinuity for all three of the data sets at approximately 130° C. For iodine exposure on Si(100) at temperatures lower than 130° C. a smaller slope in the Langmuir plot is observed. Calculations indicate that ΔH for the reaction in this temperature range is on the order of ˜7 kJ/mole. At temperatures above 130° C., a much steeper isotherm plot is obtained, resulting in ΔH for the reaction on the order of 16-32 kJ/mole, depending upon the pressure. On the Si(111) surface an opposite trend is observed, with a steeper slope present in the data below 130° C.

While no significant differences were observable in the trends based purely on the coverage vs. temperature plot, the application of a Langmuir isotherm analysis indicates that there appears to be a reactivity difference between the Si(100) and Si(111) surfaces. Additionally, the isotherm analysis suggests that two different reaction mechanisms are involved in the thermally enhanced adsorption of iodine onto monocrystalline silicon. The transition between these two mechanisms appears to occur at approximately 130° C.

This model assumes a pseudo steady-state for both iodine and silicon radicals in that they will react as soon as they are formed, rather than accumulate in the system. The mechanism suggests that the formation of silicon surface radicals is the rate-limiting step for this adsorption reaction.
I2+hv⇄2I.
I.+Si—H→Si.+HI
I.+Si.→Si—I

### EXAMPLE 3

### Analysis of the Oxygen Containing Layer Resulting from Exposing H₂O to a Cl/Si(100) Surface

A UV-Cl₂ process (25° C., 40 sec, 10 Torr, 10% Cl₂) saturates Si(100) surfaces with 0.7-0.8 ML of Cl, less than the theoretical saturation coverage of 1 ML for a monochloride surface. A detailed analysis of the chlorinated surface showed that the Cl on the Si(100) surface was bound only as silicon monochloride, SiCl, not silicon di- or tri-chloride, SiCl₂ or SiCl₃.

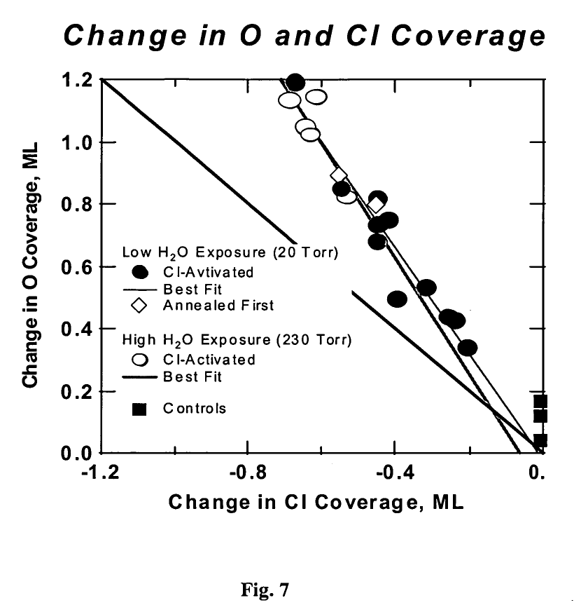

There was a linear relationship between the 0 added and the Cl removed upon H₂O exposure (45-100° C., 15-45 min, 520 Torr, 20-230 Torr H₂O) of Cl/Si(100) surfaces. FIG. 7 shows the ratio of O added to Cl removed, including both high and low H₂O flux experiments as well as two surfaces where the sample was annealed to 700° C. repeatedly to obtain a perfect Si(100) (2×1) dimer surface. The control surfaces were H/Si(100) surfaces exposed to both high and low H₂O fluxes. The ratio of O added to Cl removed was in the range 1.5 to 1.8. This result was unexpected based on the reaction SiCl(s)+H₂O(g)=SiOH(s)+HCl(g), which predicts a 1:1 ratio of O:Cl. The same ratio is maintained for both low (PH20=20 Torr) and high (PH20=230 Torr) H₂O fluxes. Annealing (700° C.×4) to remove defects from the Si(100)(2×1) surface produced the same O to Cl ratio, so surface defects are unlikely to be the cause. H/Si(100) control samples exposed to low and high fluxes of H₂O produced only a minimal increase in O coverage (<0.19 ML). This is evidence that the Cl atoms on the surface are needed to activate the reaction between H₂O and the Si(100) surface at low temperature (<100° C.). The >1 ratio of O added to Cl removed shows that both Si surface atoms and Si backbonds to the bulk substrate were activated by Cl.

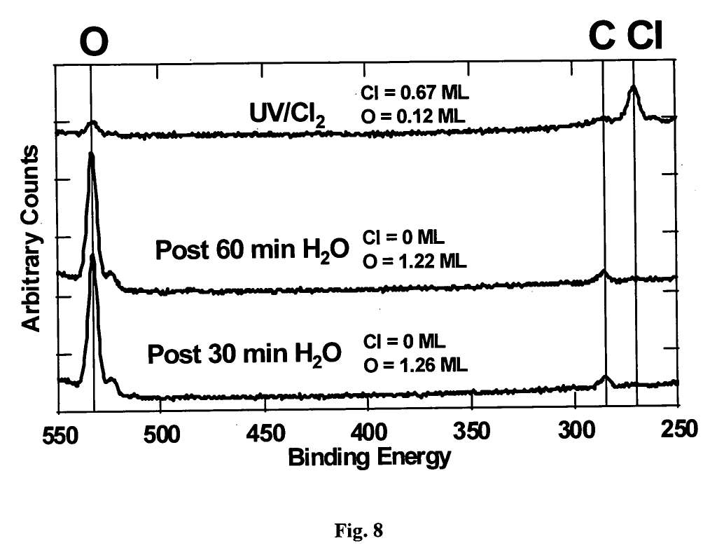

Complete removal of the Cl activation layer was achieved. FIG. 8 shows that a Cl/Si(100) surface exposed to H₂O resulted in the complete removal of the Cl with an increase in O coverage of 1.1 ML. The bottom spectrum represents the same surface exposed to an additional 30 minutes of H₂O at Pₜₒₜₐₗ=520 Torr, P(H₂O)=230 Torr, and T=100° C. with an O increase of only 0.04 ML. FIG. 8 shows XPS data before and after a high flux H₂O exposure (100° C., 60 min, 520 Torr, 230 Torr H₂O) resulting in the formation of an ultra thin oxide (increase in 0 coverage of 1.1 ML) and the complete removal of the Cl. This ultra thin oxide was relatively stable. Further exposure to H₂O (370° K, 30 min, 520 Torr, 230 Torr H₂O) resulted in only 0.04 ML increase in O coverage. A similar sample was exposed to atmosphere for 14 hours with an increase in O coverage of <0.2 ML, showing the stability of the ultra thin oxide layer in atmosphere (data not shown).

High resolution XPS analysis was performed to identify the form of the O on the surface. The Si 2p peak was analyzed before and after a H₂O exposure (100° C., 45 min, 520 Torr, 230 Torr H₂O) and a 525° C. vacuum anneal (P=1×10⁻⁹ Torr). The 525° C. anneal was chosen because it is above the temperature at which H desorbs from the surface. High resolution scans fitted with peaks representing different oxidation states of Si (data not shown) were taken from a single sample after a UV-Cl₂ process, a H₂O process and an 525° C. anneal. The post UV-Cl₂ spectrum shows the presence of Si⁺ representing the SiCl on the surface. The observation of a single Cl 2p peak confirms the presence of only monochloride. The post H₂O spectrum shows the presence of both Si⁺ and Si⁺⁴ states representing both Si—O—X and stoichiometric SiO₂. Finally, the post-annealed spectrum shows the presence of Si⁺, Si⁺³, and Si⁺⁴. The O coverage did not change after the anneal. This shows that the structure of the O on the surface changed. High resolution scans of the O is peak, reveal shifts as a result of the 525° C. anneal. The shift is from 532.9 eV to 532.3 eV or 0.6 eV, suggesting that the O is forming a more SiO₂ like structure.

### EXAMPLE 4

### Selective Deposition of Metal

It has been shown that TiCl₄(g) reacts readily with surface SiOH groups. Exposing a UV-Cl₂+H₂O processed surface to TiCl₄ (g) resulted in an increase in Ti coverage of 0.08 ML. XPS data for a control surface H/Si(100) exposed to TiCl₄ revealed only trace amounts of Ti on the surface and a UV-Cl₂+H₂O processed surface exposed to TiCl₄(g) resulting in 0.08 ML of Ti and an increase in Cl of 0.1 ML. This suggests the reactions TiCl₄(g)+SiOH(s)=SiOTiCl₃(s)+HCl(g), TiCl₄(g)+2SiOH(s)=(SiO)₂TiCl₂(s)+2 HCl(g), and TiCl₄(g)+3SiOH(s)=(SiO)₃TiCl(s)+3HCl(g), where s represents a surface group, which is consistent with the increase of 1-2 Cl for every 1 Ti added to the surface. These reactions yield a SiOH surface density of 1-1.6 SiOH/nm².

A two-step process using a halogen was used to selectively terminate a Si surface with hydroxyl/silanol (SiO-H) groups directly, without first forming an oxide as is currently done. Silanol groups have been shown to be beneficial in nucleating metal oxide layers deposited by ALD. Atomic layer depositions done on H-terminated surfaces result in three-dimensional, rough, and non-linear growth rates with low coverages of the metal. Si(100) was exposed to UV-Cl₂ (25° C., 10 Torr, 10 sccm Cl₂, 90 sccm N₂ illuminated by 1000 W Xe lamp) producing a Cl-terminated surface with up to 0.8 ML coverage. The Cl-terminated surface activated Si surface to reaction with H₂O (50° C., 100 Torr, 12.5% H₂O in N₂, 30 min). After the water exposure, the Cl coverage decreased to ˜0.5 ML and the 0 coverage increased up to 1 ML. The H₂O reacted with Si—Cl bonds on the surface forming Si—O surface bonds and HCl, which desorbed. XPS spectra after H₂O exposure of three different Si surfaces were done on the following: Cl-terminated, vacuum annealed (800° C.), and H-terminated (standard Piranha clean 4:1H₂SO₄:H₂O₂ at 110° C. for 10 min, followed by a dilute HF dip: 100:1 HF:H₂O for 5 min). The largest increase in O coverage occurred for the Cl-terminated surface, indicating that Cl activation increased the surface reactivity for the formation of an oxygen containing layer on the Si surface. In contrast to thermally grown or chemically deposited silicon oxide layers, the Cl atom termination limited growth to one monolayer of silicon dioxide and terminated the surface with hydroxyl (O—H) groups.

A metal oxide layer was formed on the H₂O activated surfaces. The reaction of TiCl₄(g) with SiOH is very favorable, and was used to investigate the initial steps of a TiO₂ ALD process as well as to identify the presence of SiOH on the surface resulting from activated and unactivated H₂O exposed Si(100) and amine surfaces. TiCl₄(g) was dosed at 200° C. at an exposure of approximately 10⁴ L (1 L=10⁻⁶ Torr for 1 s). The Ti coverages resulting from this process were measured for three different H₂O activated Si surfaces: annealed, liquid cleaned, and UV-Cl₂. The largest Ti coverage of ˜0.1 ML was produced by the Cl-terminated Si(100) surface (0.1 ML, vs. 0.06 for liquid cleaned and 0.04 for annealed at 800° C.). The coverage, which was not optimized, may be improved by modulating (1) the presence of Cl atoms on the surface, which decreased the sticking probability of TiCl₄, (2) steric hindrance or shading effect of TiCl₄ on the Cl and OH terminated surface, and (3) the formation of oxide, namely Si—O—Si, in combination with surface silanol groups during the water activation step.

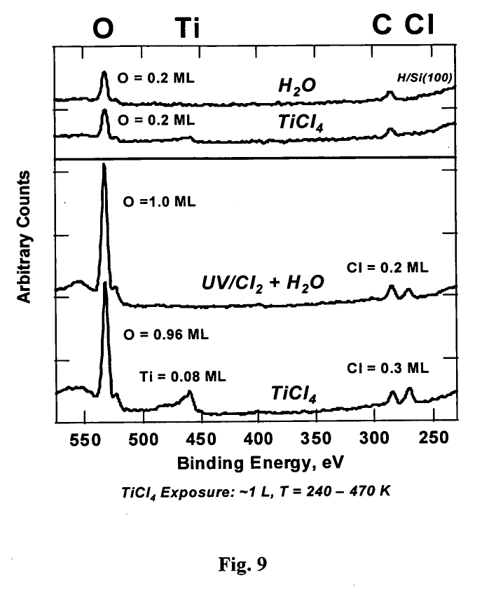

FIG. 9 shows XPS data before and after TiCl₄ exposure of a H/Si(100) surface (top) and a UVCl₂+H₂O exposure surface (bottom), illustrating the preferential binding of TiCl₄ to hydroxyl groups. The data illustrates the reaction of TiCl₄ with hydroxyl groups on the surface that were deposited using a ultraviolet light-Cl₂ process followed by exposure to water vapor to replace chlorine atoms with hydroxyl groups. The coverage of Ti is incomplete likely because of a shadowing effect of Si—TiCl₃ bound to the surface. Subsequent water and TiCl₄ exposures will complete the layer and grow subsequent layers of TiO₂. Incomplete monolayer growth is common for ALD processes.

The above described x-ray photoelectron (XPS) spectroscopy data have demonstrated that titanium metal was deposited on silanol groups bound to silicon dioxide selectively to silicon when both surfaces were exposed to a gas phase containing titanium tetrachloride (TiCl₄). The deposition temperatures were varied between 22° C. and 300° C. Ti was deposited throughout the range, but more metal is deposited at the higher end of the range. The process may further include depositing a second layer of a binary barrier layer. The layers are self-aligning in that they form only in the halogen containing regions.

Other metals besides Ti may be used in this process. These include most metals used for metallization for integrated circuits. These include a refractory electrical conductor such as titanium nitride. Generally, materials which are suitable for use in this layer comprise refractory conductors which do not readily alloy or form intermetallic compounds with the other layer(s) of metal. Examples of such materials include tungsten, titanium, cobalt, tantalum, zirconium, titanium/tungsten alloys, and nitrides of tantalum, tungsten, titanium, and zirconium.

One may also form a layer of a good electrical conductor such as aluminum, copper, silver, gold, or alloys comprising such metals. Particularly preferred is an aluminum-silicon alloy containing about 1% silicon by weight. Good electrical conductors such as the metals mentioned above typically have relatively low melting points as compared to more refractory materials such as tungsten, tantalum, and titanium nitride. The layer might have a thickness between approximately 500-20,000 angstroms.

### CONCLUSION

The present specific description is meant to exemplify and illustrate the invention and should in no way be seen as limiting the scope of the invention, which is defined by the literal and equivalent scope of the appended claims. Any patents or publications mentioned in this specification are indicative of levels of those skilled in the art to which the patent pertains and are intended to convey details of the invention which may not be explicitly set out but would be understood by workers in the field. Such patents or publications are hereby incorporated by reference to the same extent as if each was specifically and individually incorporated by reference for the purpose of describing and enabling the method or material referred to.

### REFERENCES

1. http://www.intel.com/research/silicon/mooreslaw.htm.
2. Okorn-Schmidt, H. F., Characterization of Silicon Surface Preparation Processes for Advanced Gate Dielectrics. IBM Journal of Research and Development, 1999. 43(3): p. 351-365.
3. Ma, Y., et al., Vapor-Phase SiO2 Etching and Metallic Contamination Removal in an Integrated Cluster System. Journal of Vacuum Science & Technology B, 1995. 13(4): p. 1460-1465.
4. Thompson, S., P. Packan, and M. T. Bohr, MOS Scaling: Transistor Challenges for the 21st Century. 1998.
5. International Technology Roadmap for Semiconductors, 2003 ed. 2003.
6. Yadav, G. D., Catomecon: Part One—Concept of Atom Economy. Indian Chemical Engineering, Section B, 1996. 38(4): p. 194-198.
7. Can Computer Chip Makers Reduce Environmental Impact? 1996, Stanford University News Service.
8. Perry, R., IDC Electrical Design Guide, 2004.
9. Ma, Y. and M. L. Green, In-Situ Vapor Phase Processes in an Integrated Cluster System for Pre-Gate Oxide Silicon Surface Cleaning in Electrochemical Society, 1995.
10. Bowling, R. A., et al., MMST Wafer Cleaning, Solid State Technology, 1994. 37(1): p. 61-65.
11. Buriak, J. M., Organometallic Chemistry on Silicon Surfaces: Formation of Functional Monolayers Bound Through Si—C Bonds. Chemical Communications, 1999(12): p. 1051-1060.
12. Effenberger, F., et al., Photoactivated Preparation and Patterning of Self-Assembled Monolayers with 1-Alkenes and Aldehydes on Silicon Hydride Surfaces. Angewandte Chemie-International Edition, 1998. 37(18): p. 2462-2464.
13. Boukherroub, R., et al., Insights into the Formation Mechanisms of Si—OR Monolayers from the Thermal Reactions of Alcohols and Aldehydes with Si(111)-H. Langmuir, 2000. 16(19): p. 7429-7434.
14. Mo, R. T., et al., Atomic-Scale Mechanistic Study of Iodine/Alcohol Passivated Si(100) in Electrochemical Society.
15. Finstad, C. C., et al., An Integrated HF/Vapor and UV/Cl2 Processing and Analytical Apparatus for Gas Phase Surface Preparation.
16. Wagner, C. D., et al., Empirical Atomic Sensitivity Factors for Quantitative-Analysis by Electron-Spectroscopy for Chemical-Analysis. Surface and Interface Analysis, 1981. 3(5): p. 211-225.
17. Wagner, C. D., Sensitivity Factors for XPS Analysis of Surface Atoms. Journal of Electron Spectroscopy and Related Phenomena, 1983. 32(2): p. 99-102.
18. Pierret, R. F., Semiconductor Device Fundamentals. 1996, Reading, Mass.: Addison-Wesley Publishing Company. 792.
19. Gray, D. C., et al., Photochemical Dry-Etching of Doped and Undoped Silicon-Oxides. Journal of the Electrochemical Society, 1995. 142(11): p. 3859-3863.

What is claimed is:

1. A process for manipulating surface termination on a substrate having a hydrogen atom terminated portion, comprising:
a first step of exposing a surface of said substrate to a halogen gas while the surface is also being irradiated by ultraviolet light to form a halogen surface layer on said hydrogen atom terminated substrate portion; and
a second step of exposing said halogen surface layer to a gas containing a compound of the formula R-OH, wherein R is lower alkyl to form a passivation layer;
wherein said first step and second step are done at temperatures below about 200° C. and in an inert atmosphere.

2. The process of claim 1 wherein said substrate is a semiconductor material.

3. The process of claim 2 wherein the substrate is a Group IV material.

4. The process of claim 2 wherein the substrate is a Group III/V material.

5. The process of claim 2 wherein said semiconductor material is selected from the group consisting of Si, Ge, and InSb.

6. The process of claim 1 wherein the halogen is chlorine or iodine.

7. The process of claim 1 wherein said ultraviolet light is between 190 and 400 nm.

8. The process of claim 1 further comprising the step of removing said passivation layer by heating.

9. The process of claim 8 wherein removal of said passivation layer is followed by a step of applying to the substrate a gate metal.

10. The process of claim 1 wherein the temperature is between 25° C. and 75° C.

11. The process of claim 1 wherein the inert atmosphere is a vacuum of at least 10 Torr.

12. The process of claim 11 wherein the inert atmosphere consists essentially of an inert gas selected from one or more of nitrogen, helium, neon, argon, krypton, xenon, or carbon dioxide.

13. The process of claim 1 wherein R is selected from the group consisting of ethyl, methyl propyl and oxides thereof.

14. A process for manipulating surface termination on a substrate having a hydrogen atom terminated portion, comprising:
a first step of exposing a surface of said substrate to a halogen gas while the surface is also being irradiated by ultraviolet light to form a halogen surface layer on the hydrogen atom terminated portion;
a second step of exposing said halogen surface layer to an aqueous gas to form hydroxyl groups, on the surface of the substrate; and
a third step comprising exposure to a metal halide, whereby metal is deposited only on portions of the surface of the substrate bearing hydroxyl groups,
wherein the first step and second step are done in an inert atmosphere at a temperature below about 75° C. and the third step is done at a temperature below about 200° C.

15. The process of claim 14 wherein the metal is selected from the group consisting of: tungsten, titanium, cobalt, zirconium, and alloys and compounds comprising those metals.

16. The process of claim 14 further comprising the step of heating the substrate above about 300° C. to remove residual halogen.

17. The process of claim 14 wherein the substrate further comprises an oxidized portion wherein the first second and third steps do not result in metal deposition on the oxidized portion.

18. The process of claim 17 further comprising the step of repeating the second and third steps to form multiple, aligned layers of metal.

19. The process of claim 14 wherein the inert atmosphere is provided by either a vacuum or an inert gas.

20. The process of claim 14 where all steps are performed at a temperature below about 75° C.
